(19) United States
(12) Patent Application Publication
(10) Pub. No.: US 2002/0020360 A1
(43) Pub. Date: Feb. 21, 2002

(54) Silicon wafer supporting device for supporting a silicon wafer subjected to an evaporation process on its underside

(76) Inventors: Concetto Pocorobba, Piazza Armerina (IT); Gianleonardo Grasso, Mascali (IT)

Correspondence Address: JENKENS & GILCHRIST, P.C., 3200 Fountain Place, 1445 Ross Avenue, Dallas, TX, 75202-2799, US

(21) Appl. No.: 09/826,562

(22) Filed: Apr. 4, 2001

(30) Foreign Application Priority Data
Apr. 10, 2000 (EP) 00830268.9

(51) Int. Cl. B05C 13/00; C23C 16/00

(52) U.S. Cl. 118/728; 118/503

(57) ABSTRACT

A silicon wafer supporting device, for supporting a silicon wafer whose underside is subjected to an evaporation process, including a plate-like element (10) and a plurality of bracket-like elements (12). These bracket-like elements (12) are selectively fixed to the plate-like element (10) and adapted to support at least one silicon wafer (2) at the silicon wafer's perimeter. This supporting device has at least one blind seat (11) which is formed at the lower surface of the plate-like element (10) and is adapted to accommodate the at least one silicon wafer (2) whose lower side is subjected to an evaporation process.

### FIELD OF THE INVENTION

The present invention relates generally to a wafer supporting device for supporting a silicon wafer whose underside is subjected to an evaporation process.

### BACKGROUND OF THE PRESENT INVENTION

During fabrication of an integrated circuit, silicon wafers may be subjected to an evaporation process in order to deposit metal on the underside and/or lower side of the silicon wafers. During the evaporation process, silicon wafers are supported on supporting devices along the edge of the wafer. Referring to FIG. 1, conventional supporting devices 1 have a plurality of through openings in which the silicon wafers 2, whose underside is to be subjected to an evaporation process, are arranged. Typically, the silicon wafers 2 are supported by laterally protruding portions 3 of the supporting devices 1 that extend into the through opening. Accordingly both sides and/or surfaces of each silicon wafer 2 are exposed: the wafer underside 2a (which is to be subjected to the evaporation process) and the wafer front side/upperside 2b (which should be kept unchanged). During the evaporation process, the direction of the evaporation stream, shown by the arrows 4 in FIG. 1, is such as to affect not only the underside 2a of the silicon wafer 2 but also the front side 2b thereof, thereby yielding undesirable effects. Moreover, the fact that the silicon wafer 2 is supported by the step-shaped protruding portions 3 of the supporting device 1 prevents the evaporation process from occurring at the regions of the backside of the silicon wafer 2 that contact supporting device 1, thus leaving a non-metallized annular region of a certain thickness along the underside 2a of the silicon wafer 2.

FIG. 2 is a detailed view of the region where the silicon wafer 2 rests on the protruding part 3 of the conventional supporting device 1. These conventional supporting devices 1 are generally made of steel and are subject to loss of mechanical performance due to deformation over time.

Based upon the foregoing, there is a need for an improved support device for use during an evaporation process.

### SUMMARY OF THE INVENTION

The present invention describes a device for supporting a silicon wafer whose underside is subjected to an evaporation process. This supporting device is made of a plate-like element and a number of bracket-like elements substantially fixed to the plate-like element. This device is capable of supporting at least one silicon wafer at the perimeter thereof. The plate-like element has at least one blind seat at the lower surface thereof to accommodate at least one silicon wafer. The silicon wafer's lower side is subjected to a metallization process while supported by this blind seat. This supporting device avoids the undesirable metallization of the wafer's front side and reduces the unmetallized areas on the wafer's underside.

A more complete appreciation of the present invention and the scope thereof can be obtained from the accompanying drawings which are briefly summarized below, the following detailed description of the preferred embodiment of the invention, and the appended claims.

### BRIEF DESCRIPTION OF FIGURES

FIG. 1 is a schematic partial view of a conventional silicon wafer supporting device;

FIG. 2 is a detail view of a portion of the conventional wafer supporting device of FIG. 1;

FIG. 3 is a schematic view of a wafer supporting device according to an embodiment of the present invention;

FIG. 4 is a detailed view of a portion of the wafer supporting device shown in FIG. 3;

FIG. 5 is a plan view of one of the blind seats formed in the supporting device according to an embodiment of the invention;

FIG. 6 is a partial sectional view of the wafer supporting device, taken along the line VI-VI of FIG. 5; and

FIG. 7 is a side view of one of the silicon wafer supporting brackets used in the supporting device according to an embodiment of the invention.

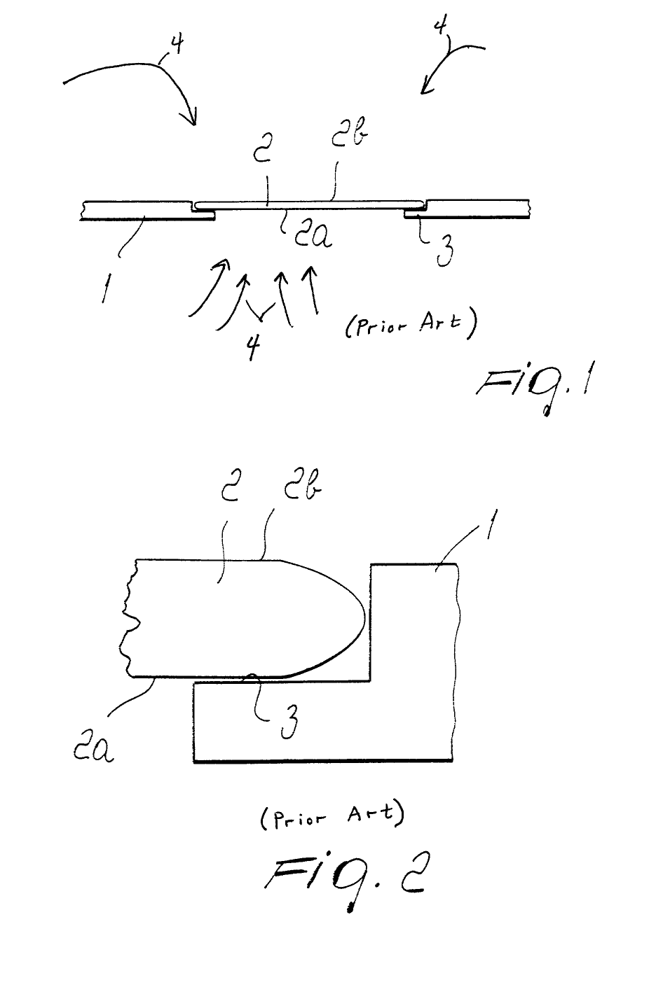

### DETAILED DESCRIPTION OF THE PREFERRED EMBODIMENT

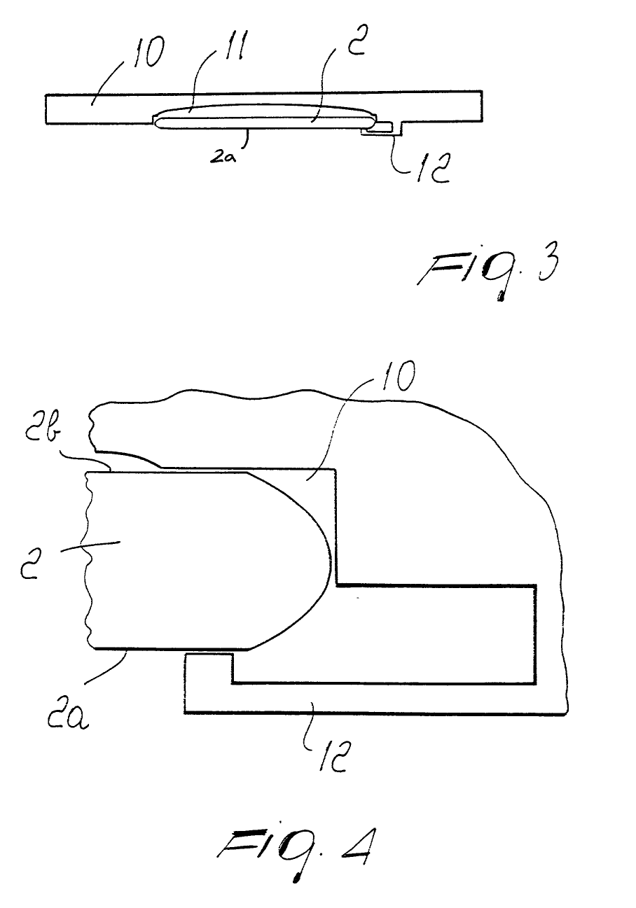

FIGS. 3 to 7 illustrate the supporting device according to a preferred embodiment of the present invention. A plate-like element 10, has at least one blind seat 11 which is adapted to accommodate at least one silicon wafer 2 therein. The silicon wafer 2 is supported within the seat 11 by a plurality of bracket-like elements 12. These bracket-like elements 12 are fixed to the supporting device 10 so as to protrude at least partially into the blind seat 11, acting as a support for the silicon wafer 2.

As shown in FIG. 4, the portion of the silicon wafer 2 that makes contact with the bracket-like element 12 is reduced with respect to the contact region of the silicon wafer 2 shown in FIG. 2.

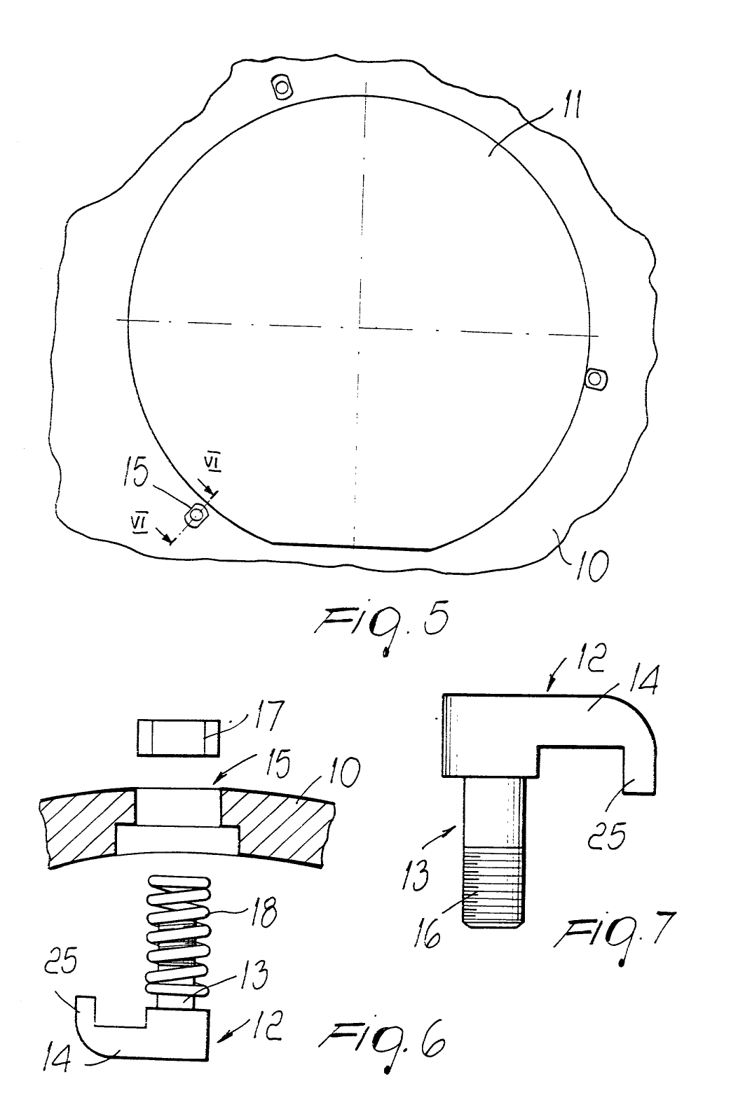

Bracket-like elements 12, for example three elements conveniently arranged with a mutual offset of 120° (FIG. 5), are selectively fixed to the supporting device 10 by anchoring them in appropriate seats 15 as shown in FIG. 6. Each seat 15 is step-shaped to form two portions having different diameters which are adapted to accommodate the bracket-like element 12.

As shown in FIG. 7, the bracket-like element 12 is substantially J-shaped. The vertical portion 13 of the bracket-like element 12 is adapted to selectively engage in the seat 15, while a horizontal portion 14 is adapted to constitute the supporting element for the silicon wafer 2. In particular, the portion 14 of the bracket-like element 12 has a raised part 25 whose longitudinal axis is substantially parallel to the longitudinal axis of the vertical portion 13 and allows the silicon wafer 2 to rest thereon. Therefore, only the portion that rests on the raised part 25 of the bracket-like element 12 is not affected by the metallization process. The bracket-like element 12 has, at the upper or outermost end of the vertical portion 13, a thread 16 which allows an engagement with a locking nut 17. This locking nut 17 is designed to fasten the bracket-like element 12 within the seat 15. An elastic means is interposed between the locking nut 17 and the bracket-like element 12 along the vertical portion 13. This elastic means, for example, could be a helical spring 18.

The supporting element for an embodiment of the present invention could have a different shape and still accomplish the same effects. For example, a preferred embodiment of the present invention could use a half circular bracket-like element. This half circular bracket-like element may be selectively fixed to the plate-like element 10 by one of its edges, as described above, with the underside 2a of the silicon wafer 2 resting on the other edge. Another embodiment of the present invention may include a bracket-like element 12 having a pointed edge for the raised part 25, so the silicon wafer 2 will be in contact with an even smaller portion of the supporting element. This allows the metallization of even more area of the silicon wafer underside 2a. Yet another embodiment of the preset invention may include the raised edge 25 of the bracket-like element 12 being of any shape and direction to allow the smallest possible contact region with the silicon wafer 2. This allows the metallization of a larger area of the silicon wafer underside 2a.

Moreover, embodiments of the present invention could have additional variations. For example, the nut 17 used to fix the bracket-like element 12 to the plate-like element 10 could be any device or component for holding the bracket-like element 12 in a substantially fixed position. The bracket-like element 12 could be held in place by any of the following attachment mechanisms: welding, clipping, or even integrally forming the bracket-like element into the plate-like element so as to extend therefrom.

In this manner, a silicon wafer 2 is accommodated from below in a blind seat 11 formed within the supporting device 10 so that the front side 2b of the silicon wafer 2 is screened or shielded by the supporting device 10 during an evaporation process. This screening is done by the blind seat 11 of the supporting device. The underside 2a of the silicon wafer 2 is exposed to the metallization process that affects the silicon wafer 2, except the thickness of the underside 2a of the silicon wafer resting on the portion 25 of the bracket-like element 12. There are a number of bracket-like elements 12 (for example three) used to adequately support the silicon wafer 2 inside the blind seat 11.

The use of a supporting device 10 according to an embodiment of the invention avoids metallic contamination of the front side 2b of the silicon wafer 2. The supporting device 10 also reduces the unmetallized regions on the underside 2a of the silicon wafer 2 at the resting portions of the silicon wafer. Additionally, the supporting device 10 could be conveniently made of titanium, to have better mechanical characteristics than conventional supporting devices that are usually made of steel. There are no through seats in the invention, only blind seats 11. This ensures substantial non-deformability of supporting device 10, with substantially constant mechanical performance over time.

As will be recognized by those skilled in the art the device is susceptible of numerous modifications and variations, all of which are within the scope of the inventive concept. The elements may be replaced with other technically equivalent elements which perform the same functionality. In practice, the materials used, so long as they are compatible with the specific use, may be any according to requirements and to the state of the art. Accordingly, the scope of patented subject matter should not be limited to any of the specific exemplary teachings discussed, but is instead defined by the following claims.

1. A silicon wafer supporting device comprising:
a plate-like element with at least one portion of said plate-like element sized to accommodate at least one silicon wafer so that an upper side of said at least one silicon wafer is covered by said at least one portion of said plate-like element, and a lower side of said at least one silicon wafer is substantially entirely exposed; and
a plurality of bracket-like elements selectively fixed to said plate-like element and adapted to support said at least one silicon wafer at a perimeter thereof.

2. The device according to claim 1, wherein said plurality of bracket-like elements are selectively fixed to said plate-like element so as to protrude from a side of said plate-like element at least partially into said at least one portion of said plate-like element.

3. The device according to claim 1, wherein each of said bracket-like elements is substantially J-shaped, a horizontal portion of said bracket-like element having, at one end, a first vertical portion extending therefrom which is a resting base for said at least one silicon wafer.

4. The device according to claim 3, wherein said bracket-like element comprises a second vertical portion which is adjacent to the horizontal portion and is substantially parallel to the first vertical portion and adapted to support said silicon wafer, said second vertical portion adjacent to the horizontal portion being selectively engaged with a seat formed in said plate-like element.

5. The device according to claim 4, wherein said bracket-like element is rigidly connected to said plate-like element by a nut; and
the device further comprises an interposed elastic member disposed between the nut and the horizontal portion of the bracket-like element.

6. The device according to claim 1, wherein said plate-like element is made of a titanium composition.

7. The device according to claim 1, further comprising a plurality of plate-like element portions sized to accommodate a plurality of silicon wafers therein.

8. An apparatus for supporting a silicon wafer comprising:
means for accommodating at least one silicon wafer, a first side of said at least one silicon wafer to be subjected to a fabrication process, and protecting a second side of the at least one silicon wafer from said fabrication process; and
means for supporting said at least one silicon wafer in said accommodating means, said supporting means being selectively fixed to said accommodating means.

9. The apparatus of claim 8, wherein said accommodating means includes a seat sized to receive the at least one silicon wafer therein.

10. The apparatus of claim 8, wherein said means for supporting the at least one silicon wafer comprises a plurality of bracket-like elements selectively fixed to said accommodating means, said bracket-like elements being capable of supporting said at least one silicon wafer along a perimeter thereof.

11. The apparatus of claim 10, wherein said plurality of bracket-like elements are substantially J-shaped, a first portion of each of said plurality of bracket-like elements is used as a resting base for said at least one silicon wafer, a second portion of each of said plurality of bracket-like elements is selectively fixed to said accommodating means.

12. The apparatus of claim 8, further comprising:
connecting means for connecting said supporting means to said accommodating means.

13. The apparatus of claim 8, wherein said accommodating means and said supporting means are made of a titanium composition.

14. A method for supporting a silicon wafer comprising the steps of:
accommodating, in a plate-like element, at least one silicon wafer whose underside is to be subjected to a fabrication process; and
supporting said at least one silicon wafer in said plate-like element.

15. The method of claim 15, wherein the accommodating step comprises protecting the upperside of the at least one silicon wafer while exposing substantially the entire underside of the at least one silicon wafer.

16. The method of claim 14, further comprising fixing each of at least two bracket-like elements to said plate-like element using a locking nut.
